(19) United States
(12) Patent Application Publication
(10) Pub. No.: US 2023/0170183 A1
(43) Pub. Date: Jun. 1, 2023

(54) MULTI-ELECTRON BEAM INSPECTION DEVICE AND MULTI-ELECTRON BEAM INSPECTION METHOD

(71) Applicant: NuFlare Technology, Inc., Yokohama-shi (JP)

(72) Inventors: Riki OGAWA, Yokohama-shi (JP); Ryoichi HIRANO, Yokohama-shi (JP); Shinji SUGIHARA, Yokohama-shi (JP); Hiromu INOUE, Yokohama-shi (JP)

(73) Assignee: NuFlare Technology, Inc., Yokohama-shi (JP)

(21) Appl. No.: 17/995,441

(22) PCT Filed: Feb. 3, 2021
(86) PCT No.: PCT/JP2021/003885

§ 371 Date: Oct. 4, 2022

(30) Foreign Application Priority Data
Apr. 6, 2020 (JP) 2020-068594

(51) Int. Cl. H01J 37/317; H01J 37/244; H01J 37/28

(52) U.S. Cl. CPC H01J 37/3177; H01J 37/28; H01J 37/244; H01J 2237/2817

(57) ABSTRACT

A multi-electron beam inspection apparatus includes a multi-detector that includes a plurality of detection sensors each of which detects a secondary electron beam emitted due to that a target object is irradiated with a primary electron beam individually preset in multiple secondary electron beams emitted because the target object is irradiated with multiple primary electron beams, a reference image data generation circuit that generates reference image data of a position irradiated with each primary electron beam, based on design data serving as a basis of the pattern formed on the target object, a synthesis circuit that synthesizes, for each primary electron beam, the reference image data of the position irradiated with a primary electron beam concerned and portions of reference image data of positions irradiated with other primary electron beams different from the primary electron beam concerned, and a comparison circuit that compares synthetic reference image data having been synthesized, and secondary electron image data based on a value detected by the detection sensor which detects a secondary electron beam due to irradiation with the primary electron beam concerned.

### TECHNICAL FIELD

This application is based upon and claims the benefit of priority from Japanese Patent Application No. 2020-068594 filed on Apr. 6, 2020 in Japan, the contents of which are incorporated herein.

The present invention relates to a multi-electron beam inspection apparatus and a multi-electron beam inspection method. For example, it relates to an inspection apparatus for performing inspection by using a secondary electron image of a pattern emitted by irradiation with multiple electron beams.

### BACKGROUND ART

In recent years, with advances in high integration and large capacity of the LSI (Large Scale Integrated circuits), the circuit line width required for semiconductor elements is becoming increasingly narrower. Since LSI manufacturing requires an enormous production cost, it is essential to improve the yield. However, as typified by 1 gigabit DRAMs (Dynamic Random Access Memories), the size of patterns that make up the LSI becomes the order of nanometers from submicrons. Also, in recent years, with miniaturization of dimensions of LSI patterns formed on a semiconductor wafer, dimensions to be detected as a pattern defect have become extremely small. Therefore, the pattern inspection apparatus which inspects defects of ultrafine patterns exposed and transferred onto a semiconductor wafer needs to be highly accurate. Further, one of major factors that decrease the yield is due to pattern defects on the mask used for exposing and transferring ultrafine patterns onto a semiconductor wafer by the photolithography technology. Therefore, the pattern inspection apparatus for inspecting defects on an exposure transfer mask used in manufacturing LSI needs to be highly accurate.

As an inspection method, there is known a method of comparing a measured image acquired by imaging a pattern formed on a substrate, such as a semiconductor wafer or a lithography mask, with design data or with another measured image acquired by imaging an identical pattern on the substrate. For example, as a pattern inspection method, there are “die-to-die inspection” and “die-to-database inspection”. The “die-to-die inspection” method compares data of measured images acquired by imaging identical patterns at different positions on the same substrate. The “die-to-database inspection” method generates, based on design data of a pattern, design image data (reference image), and compares it with a measured image being measured data acquired by imaging the pattern. Acquired images are transmitted as measured data to a comparison circuit. After performing alignment between the images, the comparison circuit compares the measured data with reference data according to an appropriate algorithm, and determines that there is a pattern defect if the compared data do not match each other.

With respect to the pattern inspection apparatus described above, in addition to the apparatus that irradiates an inspection target substrate with laser beams in order to obtain a transmission image or a reflection image, there has been developed another inspection apparatus that acquires a pattern image by scanning an inspection target substrate with primary electron beams and detecting secondary electrons emitted from the inspection target substrate due to the irradiation with the primary electron beams. With regard to inspection apparatuses using electron beams, development of apparatuses using multiple electron beams is also in progress. In the inspection apparatus using multiple electron beams, a sensor is disposed which detects a secondary electron due to irradiation with each of multiple primary electron beams in order to acquire an image for each beam. However, since the multiple primary electron beams are applied simultaneously, there is a problem that, into the sensor for each beam, a secondary electron of a beam not concerned is mixed, namely occurrence of so-called crosstalk. Crosstalk causes a noise, and therefore, the image precision of a measured image is degraded, thus deteriorating the inspection accuracy. It is necessary, in order to avoid crosstalk, to reduce the electron energy of primary electron beams on the target object surface, however, which decreases the number of secondary electrons to be generated. Therefore, it becomes necessary to increase the irradiation time to obtain the necessary number of secondary electrons for desired image precision, resulting in degradation of the throughput.

There is disclosed a method of making an interval between primary electron beams larger than aberration of a secondary optical system in order not to have crosstalk between a plurality of secondary electron beams (e.g., refer to Patent Literature 1).

### CITATION LIST

### Patent Literature

Patent Literature 1: JP-A-2002-260571

### SUMMARY OF INVENTION

### Technical Problem

One aspect of the present invention provides an inspection apparatus and method that can perform an inspection with high accuracy even when, into the sensor for each beam, a secondary electron of a beam not concerned is mixed, namely occurrence of so-called crosstalk.

### Solution to Problem

According to one aspect of the present invention, a multi-electron beam inspection apparatus includes
a stage configured to mount thereon a target object on which a pattern is formed;
a primary electron optical system configured to apply multiple primary electron beams to the target object;
a multi-detector configured to include a plurality of detection sensors each of which detects a secondary electron beam emitted due to that the target object is irradiated with a primary electron beam individually preset in the multiple secondary electron beams emitted because the target object is irradiated with the multiple primary electron beams;
a reference image data generation circuit configured to generate reference image data of a position irradiated with each primary electron beam, based on design data serving as a basis of the pattern formed on the target object;
a synthesis circuit configured to synthesize, for the each primary electron beam, the reference image data of the position irradiated with a primary electron beam concerned and portions of a plurality of reference image data of positions irradiated with other primary electron beams different from the primary electron beam concerned; and
a comparison circuit configured to compare synthetic reference image data having been synthesized, and secondary electron image data based on a value detected by the detection sensor which detects a secondary electron beam due to irradiation with the primary electron beam concerned.

According to another aspect of the present invention, a multi-electron beam inspection method includes
applying multiple primary electron beams to a target object on which a pattern is formed;
detecting, by using a multi-detector which includes a plurality of detection sensors each of which detects a secondary electron beam emitted due to that the target object is irradiated with a primary electron beam individually preset in multiple secondary electron beams emitted because the target object is irradiated with the multiple primary electron beams, the multiple secondary electron beams emitted due to that the target object is irradiated with the multiple primary electron beams, and acquiring secondary electron image data of each of the detection sensors, based on a detected value of the each of the detection sensors;
generating reference image data of a position irradiated with each primary electron beam, based on design data serving as a basis of the pattern formed on the target object;
synthesizing, for the each primary electron beam, the reference image data of the position irradiated with the primary electron beam concerned and portions of a plurality of reference image data of positions irradiated with other primary electron beams different from the primary electron beam concerned; and
comparing synthetic reference image data having been synthesized, and secondary electron image data based on a value detected by the detection sensor which detects a secondary electron beam due to irradiation with the primary electron beam concerned.

### Advantageous Effects of Invention

According to one aspect of the present invention, it is possible to perform inspection with a high accuracy even when, into the sensor for each beam, a secondary electron of a beam not concerned is mixed, namely occurrence of so-called crosstalk.

### BRIEF DESCRIPTION OF DRAWINGS

FIG. 1 is a diagram showing an example of a configuration of a pattern inspection apparatus according to an embodiment 1.

FIG. 2 is a conceptual diagram showing a configuration of a shaping aperture array substrate according to the embodiment 1.

FIG. 3 is an illustration of an example of a plurality of chip regions formed on a semiconductor substrate according to the embodiment 1.

FIG. 4 is an illustration of a scanning operation with multiple beams according to the embodiment 1.

FIG. 5 is a diagram showing an example of a spread of a secondary electron beam per primary electron beam according to the embodiment 1.

FIG. 6 is a flowchart showing main steps of an inspection method according to the embodiment 1.

FIG. 7 is an illustration of sub-irradiation region scanning, and a secondary electron intensity to be measured according to the embodiment 1.

FIG. 8 is an illustration of an example of a secondary electron intensity map according to the embodiment 1.

FIG. 9 is an illustration of an example of a gain map according to the embodiment 1.

FIG. 10 is an illustration of an example of a configuration of each gain value according to the embodiment 1.

FIG. 11 is an illustration of a method for generating a synthetic reference image according to the embodiment 1.

FIG. 12 is a block diagram showing an example of a configuration in a comparison circuit according to the embodiment 1.

### DESCRIPTION OF EMBODIMENTS

### Embodiment 1

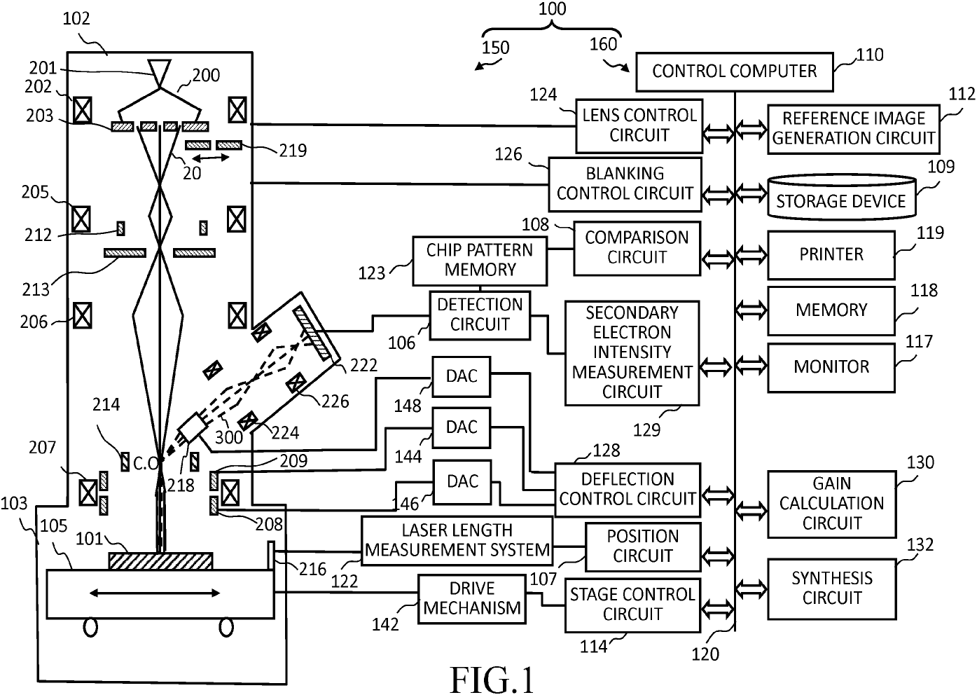

FIG. 1 is a diagram showing an example of a configuration of a pattern inspection apparatus 100 according to an embodiment 1. In FIG. 1, the inspection apparatus 100 for inspecting a pattern formed on a substrate is an example of a multi-electron beam inspection apparatus. The inspection apparatus 100 includes an image acquisition mechanism 150 (secondary electron image acquisition mechanism) and a control system circuit 160. The image acquisition mechanism 150 includes an electron beam column 102 (electron optical column) and an inspection chamber 103. In the electron beam column 102, there are disposed an electron gun 201, an electromagnetic lens 202, a shaping aperture array substrate 203, a beam selection aperture substrate 219, an electromagnetic lens 205, a bundle blanking deflector 212, a limiting aperture substrate 213, an electromagnetic lens 206, an electromagnetic lens 207 (objective lens), a main deflector 208, a sub deflector 209, a beam separator 214, a deflector 218, an electromagnetic lens 224, an electromagnetic lens 226, and a multi-detector 222. In the case of FIG. 1, a primary electron optical system which irradiates a substrate 101 with multiple primary electron beams is composed of the electron gun 201, the electromagnetic lens 202, the shaping aperture array substrate 203, the beam selection aperture substrate 219, the electromagnetic lens 205, the bundle blanking deflector 212, the limiting aperture substrate 213, the electromagnetic lens 206, the electromagnetic lens 207 (objective lens), the main deflector 208, and the sub deflector 209. A secondary electron optical system which irradiates the multi-detector 222 with multiple secondary electron beams is composed of the beam separator 214, the deflector 218, the electromagnetic lens 224, and the electromagnetic lens 226.

In the inspection chamber 103, there is disposed a stage 105 movable at least in the x, y and z directions. The substrate 101 (target object) to be inspected is mounted on the stage 105. The substrate 101 may be an exposure mask substrate, or a semiconductor substrate such as a silicon wafer. In the case of the substrate 101 being a semiconductor substrate, a plurality of chip patterns (wafer dies) are formed on the semiconductor substrate. In the case of the substrate 101 being an exposure mask substrate, a chip pattern is formed on the exposure mask substrate. The chip pattern is composed of a plurality of figure patterns. When the chip pattern formed on the exposure mask substrate is exposed/transferred onto the semiconductor substrate a plurality of times, a plurality of chip patterns (wafer dies) are formed on the semiconductor substrate. The case of the substrate 101 being a semiconductor substrate is mainly described below. The substrate 101 is placed, with its pattern-forming surface facing upward, on the stage 105, for example. Further, on the stage 105, there is disposed a mirror 216 which reflects a laser beam for measuring a laser length emitted from a laser length measurement system 122 arranged outside the inspection chamber 103. The multi-detector 222 is connected, at the outside of the electron beam column 102, to a detection circuit 106.

In the control system circuit 160, a control computer 110 which controls the whole of the inspection apparatus 100 is connected, through a bus 120, to a position circuit 107, a comparison circuit 108, a reference image generation circuit 112, a stage control circuit 114, a lens control circuit 124, a blanking control circuit 126, a deflection control circuit 128, a secondary electron intensity measurement circuit 129, a gain calculation circuit 130, a synthesis circuit 132, a storage device 109 such as a magnetic disk drive, a monitor 117, and a memory 118. The deflection control circuit 128 is connected to DAC (digital-to-analog conversion) amplifiers 144, 146 and 148. The DAC amplifier 146 is connected to the main deflector 208, and the DAC amplifier 144 is connected to the sub deflector 209. The DAC amplifier 148 is connected to the deflector 218.

The detection circuit 106 is connected to a chip pattern memory 123 and the secondary electron intensity measurement circuit 129. The chip pattern memory 123 is connected to the comparison circuit 108. The stage 105 is driven by a drive mechanism 142 under the control of the stage control circuit 114. In the drive mechanism 142, a drive system such as a three (x-, y-, and θ-) axis motor which provides drive in the directions of x, y, and θ in the stage coordinate system is configured, and therefore, the stage 105 can be moved in the x, y, and θ directions. A step motor, for example, can be used as each of these x, y, and θ motors (not shown). The stage 105 is movable in the horizontal direction and the rotation direction by the x-, y-, and θ-axis motors. Further, the stage 105 is movable in the z direction (height direction) by using a piezoelectric element, etc., for example, in the drive mechanism 142. The movement position of the stage 105 is measured by the laser length measurement system 122, and supplied to the position circuit 107. Based on the principle of laser interferometry, the laser length measurement system 122 measures the position of the stage 105 by receiving a reflected light from the mirror 216. In the stage coordinate system, the x, y, and 6 directions are set, for example, with respect to a plane perpendicular to the optical axis (center axis of electron trajectory) of the multiple primary electron beams.

The electromagnetic lenses 202, 205, 206, 207 (objective lens), 224 and 226, and the beam separator 214 are controlled by the lens control circuit 124. The bundle blanking deflector 212 is composed of two or more electrodes, and each electrode is controlled by the blanking control circuit 126 through a DAC amplifier (not shown). The sub deflector 209 is composed of four or more electrodes, and each electrode is controlled by the deflection control circuit 128 through the DAC amplifier 144. The main deflector 208 is composed of four or more electrodes, and each electrode is controlled by the deflection control circuit 128 through the DAC amplifier 146. The deflector 218 is composed of four or more electrodes, and each electrode is controlled by the deflection control circuit 128 through the DAC amplifier 148.

In the beam selection aperture substrate 219, a passage hole through which one beam can pass is formed in the central part, for example. The beam selection aperture substrate 219 is configured to be movable in the direction (two-dimensional direction) perpendicular to the center axis (optical axis) of the trajectory of the multiple primary electron beams by the drive mechanism (not shown).

To the electron gun 201, there is connected a high voltage power supply circuit (not shown). The high voltage power supply circuit applies an acceleration voltage between a filament (cathode) and an extraction electrode (anode) (which are not shown) in the electron gun 201. In addition to the applying the acceleration voltage, a voltage is applied to another extraction electrode (Wehnelt), and the cathode is heated to a predetermined temperature, and thereby, electrons from the cathode are accelerated to be emitted as an electron beam 200.

FIG. 1 shows configuration necessary for describing the embodiment 1. Other configuration generally necessary for the inspection apparatus 100 may also be included therein.

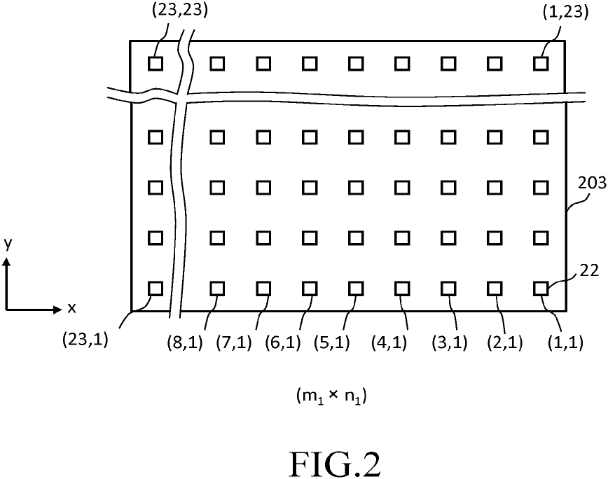

FIG. 2 is a conceptual diagram showing a configuration of a shaping aperture array substrate according to the embodiment 1. As shown in FIG. 2, holes (openings) 22 of m₁ columns wide (in the x direction) × n₁ rows long (in the y direction) are two-dimensionally formed in the x and y directions at a predetermined arrangement pitch in the shaping aperture array substrate 203, where one of m₁ and n₁ is an integer of 2 or more, and the other is an integer of 1 or more. In the case of FIG. 2, 23 ×23 holes (openings) 22 are formed. Ideally, each of the holes 22 is a rectangle having the same dimension, shape, and size. Alternatively, ideally, each of the holes 22 may be a circle with the same outer diameter. m₁×n₁(=N) multiple primary electron beams 20 are formed by letting portions of the electron beam 200 individually pass through a plurality of holes 22.

Next, operations of the image acquisition mechanism 150 in the inspection apparatus 100 will be described below.

The electron beam 200 emitted from the electron gun 201 (emission source) is refracted by the electromagnetic lens 202, and illuminates the whole of the shaping aperture array substrate 203. As shown in FIG. 2, a plurality of holes 22 (openings) are formed in the shaping aperture array substrate 203. The region including all the plurality of holes 22 is irradiated by the electron beam 200. The multiple primary electron beams 20 are formed by letting portions of the electron beam 200 applied to the positions of the plurality of holes 22 individually pass through the plurality of holes 22 in the shaping aperture array substrate 203. At the time of usual image acquisition, the beam selection aperture substrate 219 retreats to a position where it does not interfere with the multiple primary electron beams 20.

The formed multiple primary electron beams 20 are individually refracted by the electromagnetic lenses 205 and 206, and travel to the electromagnetic lens 207 (objective lens), while repeating forming an intermediate image and a crossover, passing through the beam separator 214 disposed at the crossover position of each beam of the multiple primary electron beams 20. Then, the electromagnetic lens 207 focuses the multiple primary electron beams 20 onto the substrate 101. The multiple primary electron beams 20 having been focused on the substrate 101 (target object) by the electromagnetic lens 207 (objective lens) are collectively deflected by the main deflector 208 and the sub deflector 209 to irradiate respective beam irradiation positions on the substrate 101. When all of the multiple primary electron beams 20 are collectively deflected by the bundle blanking deflector 212, they deviate from the hole in the center of the limiting aperture substrate 213 and are blocked by the limiting aperture substrate 213. By contrast, the multiple primary electron beams 20 which were not deflected by the bundle blanking deflector 212 pass through the hole in the center of the limiting aperture substrate 213 as shown in FIG. 1. Blanking control is provided by On/Off of the bundle blanking deflector 212, and thus On/Off of the beams is collectively controlled. In this way, the limiting aperture substrate 213 blocks the multiple primary electron beams 20 which were deflected to be in a beam off condition by the bundle blanking deflector 212. Then, the multiple primary electron beams 20 for inspection (for image acquisition) are formed by the beams having been made during from becoming “beam On” to becoming “beam Off” and having passed through the limiting aperture substrate 213.

When desired positions on the substrate 101 are irradiated with the multiple primary electron beams 20, a flux of secondary electrons (multiple secondary electron beams 300) including reflected electrons, each corresponding to each of the multiple primary electron beams 20, is emitted from the substrate 101 due to the irradiation with the multiple primary electron beams 20.

The multiple secondary electron beams 300 emitted from the substrate 101 travel to the beam separator 214 through the electromagnetic lens 207.

Here, the beam separator 214 generates an electric field and a magnetic field to be orthogonal to each other in a plane perpendicular to the traveling direction of the center beam (the electron trajectory center axis) of the multiple primary electron beams 20. The electric field exerts a force in a fixed direction regardless of the traveling direction of electrons. In contrast, the magnetic field exerts a force according to Fleming’s lefthand rule. Therefore, the direction of force acting on electrons can be changed depending on the entering direction of electrons. With respect to the multiple primary electron beams 20 entering the beam separator 214 from above, since the forces due to the electric field and the magnetic field cancel each other out, the multiple primary electron beams 20 travel straight downward. In contrast, with respect to the multiple secondary electron beams 300 entering the beam separator 214 from below, since both the forces due to the electric field and the magnetic field are exerted in the same direction, the beams 300 are bent obliquely upward, and separated from the multiple primary electron beams 20.

The multiple secondary electron beams 300 having been bent obliquely upward and separated from the multiple primary electron beams 20 are further bent by the deflector 218, and projected onto the multi-detector 222 while being refracted by the electromagnetic lenses 224 and 226. The multi-detector 222 detects the projected multiple secondary electron beams 300. Reflected electrons and secondary electrons may be projected on the multi-detector 222, or it is also acceptable that reflected electrons are emitted along the way and remaining secondary electrons are projected. The multi-detector 222 includes a two-dimensional sensor to be described later. Then, each secondary electron of the multiple secondary electron beams 300 collides with a corresponding region of the two-dimensional sensor, thereby generating electrons, and secondary electron image data is generated for each pixel. In other words, in the multi-detector 222, a detection sensor is disposed for each primary electron beam 10i of the multiple primary electron beams 20, where i indicates an index, and i=1 to 529 in the case of the multiple primary electron beams 20 of 23 ×23 beams. Then, the detection sensor detects a corresponding secondary electron beam emitted by irradiation with each primary electron beam 10i. Therefore, each of a plurality of detection sensors in the multi-detector 222 detects an intensity signal of a secondary electron beam for an image due to irradiation with an associated primary electron beam 10i. The intensity signal detected by the multi-detector 222 is output to the detection circuit 106.

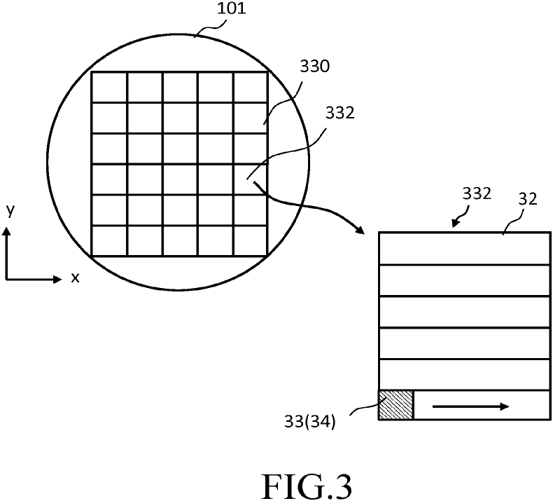

FIG. 3 is an illustration of an example of a plurality of chip regions formed on a semiconductor substrate, according to the embodiment 1. In FIG. 3, in the case of the substrate 101 being a semiconductor substrate (wafer), a plurality of chips (wafer dies) 332 are formed in a two-dimensional array in an inspection region 330 of the semiconductor substrate (wafer). With respect to each chip 332, a mask pattern for one chip formed on an exposure mask substrate is reduced to, for example, ¼, and exposed/transferred onto each chip 332 by an exposure device (stepper) (not shown). The region of each chip 332 is divided in the y direction into a plurality of stripe regions 32 by a predetermined width, for example. The scanning operation by the image acquisition mechanism 150 is carried out, for example, for each stripe region 32. The operation of scanning the stripe region 32 advances relatively in the x direction while the stage 105 is moved in the -x direction, for example. Each stripe region 32 is divided in the longitudinal direction into a plurality of frame regions 33. Beam application to a target frame region 33 is achieved by collectively deflecting all the multiple primary electron beams 20 by the main deflector 208.

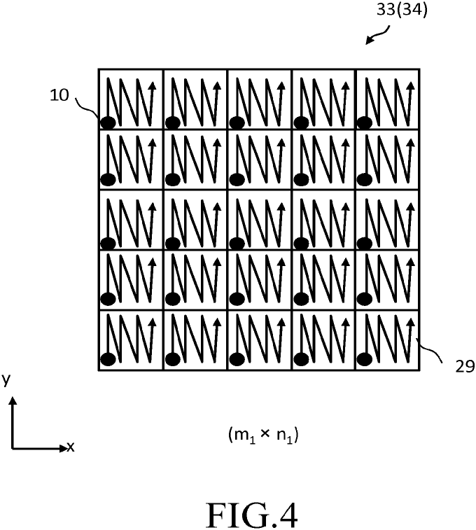

FIG. 4 is an illustration of a scanning operation with multiple beams according to the embodiment 1. FIG. 4 shows the case of multiple primary electron beams 20 of 5 rows × 5 columns. The size of an irradiation region 34 which can be irradiated by one irradiation with the multiple primary electron beams 20 is defined by (x direction size obtained by multiplying a beam pitch in the x direction of the multiple primary electron beams 20 on the substrate 101 by the number of beams in the x direction)×(y direction size obtained by multiplying a beam pitch in the y direction of the multiple primary electron beams 20 on the substrate 101 by the number of beams in the y direction). Preferably, the width of each stripe region 32 is set to be the same as the size in the y direction of the irradiation region 34, or to be the size reduced by the width of the scanning margin. In the case of FIGS. 3 and 4, the irradiation region 34 and the frame region 33 are of the same size. However, it is not limited thereto. The irradiation region 34 may be smaller than the frame region 33, or larger than it. The inside of a sub-irradiation region 29 is irradiated and scanned with each beam of the multiple primary electron beams 20, where the sub-irradiation region 29 is surrounded by the beam pitch in the x direction and the beam pitch in the y direction and the beam concerned itself is located therein. Each primary electron beam 10 of the multiple primary electron beams 20 is associated with any one of the sub-irradiation regions 29 which are different from each other. At the time of each shot, each primary electron beam 10 is applied to the same position in the associated sub-irradiation region 29. The primary electron beam 10 is moved in the sub-irradiation region 29 by collective deflection of all the multiple primary electron beams 20 by the sub deflector 209. By repeating this operation, the inside of one sub-irradiation region 29 is irradiated with one primary electron beam 10 in order. Then, when scanning of one sub-irradiation region 29 is completed, the irradiation position is moved to an adjacent frame region 33 in the same stripe region 32 by collectively deflecting all of the multiple primary electron beams 20 by the main deflector 208. By repeating this operation, the inside of the stripe region 32 is irradiated in order. After completing scanning of one stripe region 32, the irradiation position is moved to the next stripe region 32 by moving the stage 105 and/or by collectively deflecting all of the multiple primary electron beams 20 by the main deflector 208. As described above, a secondary electron image of each sub-irradiation region 29 is acquired by irradiation with each primary electron beam 10i. By combining secondary electron images of respective sub-irradiation regions 29, a secondary electron image of the frame region 33, a secondary electron image of the stripe region 32, or a secondary electron image of the chip 332 is configured.

It is also preferable to group, for example, a plurality of chips 332 aligned in the x direction in the same group, and to divide each group into a plurality of stripe regions 32 by a predetermined width in the y direction, for example. Then, moving between stripe regions 32 is not limited to the moving in each chip 332, and it is also preferable to move in each group.

When the multiple primary electron beams 20 irradiate the substrate 101 while the stage 105 is continuously moving, the main deflector 208 executes a tracking operation by performing collective deflection so that the irradiation position of the multiple primary electron beams 20 may follow the movement of the stage 105. Therefore, the emission position of the multiple secondary electron beams 300 changes every second with respect to the trajectory central axis of the multiple primary electron beams 20. Similarly, when the inside of the sub-irradiation region 29 is scanned, the emission position of each secondary electron beam changes every second in the sub-irradiation region 29. Thus, the deflector 218 collectively deflects the multiple secondary electron beams 300 so that each secondary electron beam whose emission position has changed as described above may be applied to a corresponding detection region of the multi-detector 222.

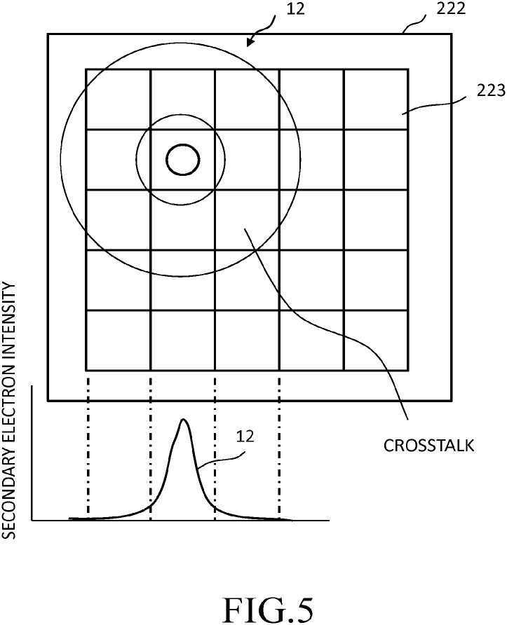

FIG. 5 is a diagram showing an example of a spread of a secondary electron beam per primary electron beam according to the embodiment 1. FIG. 5 shows the case of the multiple primary electron beams 20 of 5 rows by 5 columns. A plurality of detection sensors 223, whose number is corresponding to the number of the multiple primary electron beams 20, are two-dimensionally arranged in the multi-detector 222. The plurality of detection sensors 223 are for detecting a secondary electron beam 12 emitted due to that the substrate 101 is irradiated with the primary electron beam 10 individually preset in the multiple secondary electron beams 300 emitted because the substrate 101 is irradiated with the multiple primary electron beams 20. However, in order to obtain a desired throughput for inspection processing using the inspection apparatus 100, it is necessary to irradiate the substrate 101 with an electron energy corresponding to the throughput. In such a case, there is a problem that, into the detection sensor 223 for each primary electron beam 10, a secondary electron of the primary electron beam 10 not concerned is mixed, namely occurrence of so-called crosstalk. In the case of FIG. 5, a state is shown where the secondary electron beam 12 which should be incident on the detection sensor 223 in the second column from the left and fourth row from the bottom spreads, and therefore, a portion of the secondary electron is mixed in other surrounding detection sensors 223. Although most of the secondary electron beam 12 due to irradiation with the primary electron beam 10 concerned enters the detection sensor 223 preset for the primary electron beam 10 concerned, some of the secondary electron enters surrounding detection sensors 223 for other beams. The larger the electron energy of the multiple primary electron beams 20 on the substrate 101 becomes, the wider the distribution of the secondary electron spreads. In the scanning operation with multiple beams, since the multiple primary electron beams 20 are simultaneously applied, secondary electron information resulting from irradiation with primary electron beams not concerned is also included in secondary electron data detected by the detection sensor 223 for each beam. Such crosstalk causes a noise, and therefore, the image precision of a measured image is degraded.

Meanwhile, a reference image to be used for comparison when inspecting a measured image is generated based on design data being the basis of a figure pattern formed on the substrate 101, for example. Therefore, if a measured image (inspection image: secondary electron image) including a crosstalk image is compared with a reference image generated based on design data, since there is a difference between the images, it may be determined as a defect in spite of not being a defect, that is, a so-called pseudo defect may be generated. Thus, crosstalk degrades the inspection accuracy. It is necessary, in order to avoid crosstalk, to reduce the electron energy of the primary electron beam 10 on the surface of the substrate 101, however, which decreases the number of secondary electrons to be generated. Therefore, it becomes necessary to lengthen the irradiation time to obtain the number of secondary electrons required for desired image precision, resulting in degradation of the throughput. Then, according to the embodiment 1, not avoiding a crosstalk, but, in contrast, synthesizing information equivalent to a crosstalk component into reference image data of each pixel configuring a reference image, after matching the reference image with the measured image which has been degraded, comparison is performed. It is specifically described below.

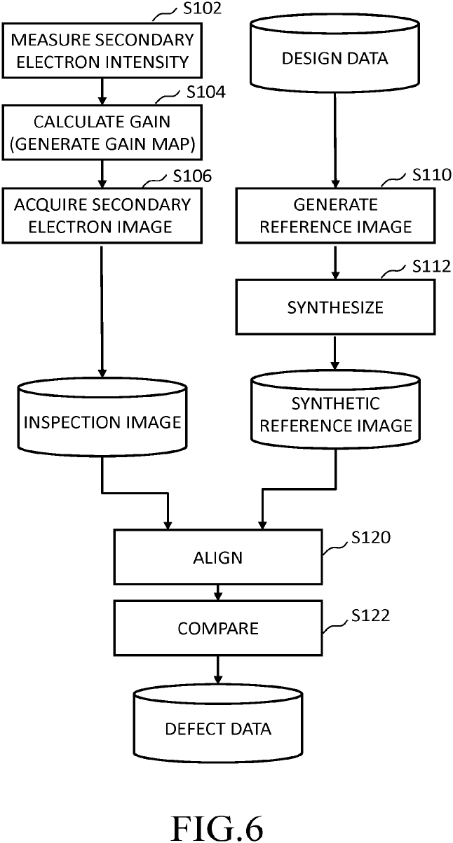

FIG. 6 is a flowchart showing main steps of an inspection method according to the embodiment 1. In FIG. 6, the inspection method of the embodiment 1 executes a series of steps: a secondary electron intensity measurement step (S102), a gain calculation step (S104), a secondary electron image acquisition step (S106), a reference image generation step (S110), a synthesis step (S112), an alignment step (S120), and a comparison step (S122).

In the secondary electron intensity measurement step (S102), the secondary electron intensity measurement circuit 129 measures, for each primary electron beam 10 of the multiple primary electron beams 20, a secondary electron intensity detected by each detection sensor 223 of the multi-detector 222. Specifically, it operates as follows: First, the secondary electron intensity measurement circuit 129 selects one primary electron beam 10 which is to be passed through the passage hole of the beam selection aperture substrate 219 from the multiple primary electron beams 20 by moving the beam selection aperture substrate 219. Other primary electron beams 10 are blocked by the beam selection aperture substrate 219. The inside of the sub-irradiation region 29 is scanned with the one primary electron beam 10. As the method of scanning, the irradiation position (pixel) of the primary electron beam 10 is moved in order by deflection by the sub deflector 209 as described above. Since it is here sufficient to know the difference among secondary electron intensities, due to irradiation of the same primary electron beam, detected by respective detection sensors 223, an evaluation substrate on which no pattern is formed may be irradiated with the primary electron beam 10, for example. By using such an evaluation substrate with no pattern formed thereon, the effect can be obtained that characteristics of respective sub-irradiation regions become uniform. However, an evaluation substrate with a pattern formed thereon may be used.

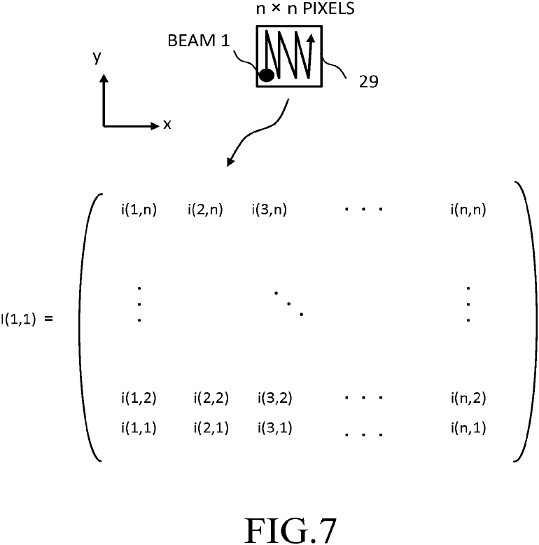

FIG. 7 is an illustration of sub-irradiation region scanning, and a secondary electron intensity to be measured according to the embodiment 1. FIG. 7 show the case of scanning the inside of the sub-irradiation region 29 with a beam 1 in N×N multiple primary electron beams 20, for example. The sub-irradiation region 29 is the size of n_{×}n pixels, for example. It is composed of 1000×1000 pixels, for example. As a pixel size, it is preferable to be about as large as the beam size of the primary electron beam 10, for example. However, it is not limited thereto. The pixel size may be smaller than the beam size of the primary electron beam 10. Alternatively, although the resolution of an image becomes low, the pixel size may be larger than the beam size of the primary electron beam 10. When irradiating each pixel with the beam 1 in order, a secondary electron beam due to irradiation of each pixel by the beam 1 is detected in order by the detection sensor 223 for the beam 1 of the multi-detector 222. If the distribution of the secondary electron beam spreads wider than the region of the detection sensor 223 for the beam concerned as shown in FIG. 5, it may be simultaneously detected also by the detection sensors 223 for other beams in order. The intensity signal detected by the multi-detector 222 is output to the detection circuit 106 in the order of measurement. In the detection circuit 106, detected data in analog form is converted into digital data by an A-D converter (not shown), and output to the secondary electron intensity measurement circuit 129. Using an input intensity signal, the secondary electron intensity measurement circuit 129 measures a secondary electron intensity I (1,1) configured by a map whose elements are secondary electron intensities i(1,1) to i(n,n) of respective pixels. (a,b) of the secondary electron intensity i(a,b) of each pixel indicates coordinates of each pixel, thus becoming one of values a=1 to a=n, and b=1 to b=n.

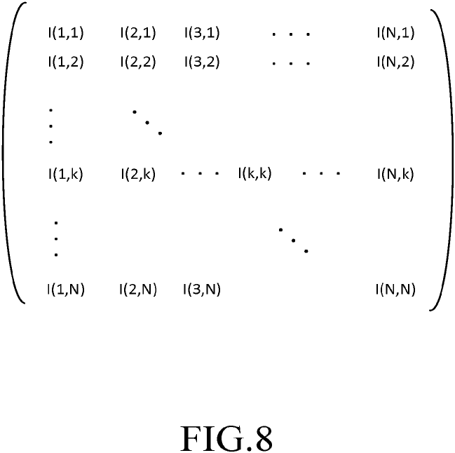

FIG. 8 is an illustration of an example of a secondary electron intensity map according to the embodiment 1. In FIG. 8, with respect to a secondary electron intensity I(A,B) being an element of a secondary electron intensity map, A indicates a beam number and B indicates a detection sensor number. A is one of values 1 to N, and B is one of 1 to N. Secondary electron intensities I (1,1) to I(1,N) can be measured by scanning, with the beam 1, the inside of the sub-irradiation region 29 for the beam 1. By selecting a target primary electron beam 10 in order by moving the beam selection aperture substrate 219, secondary electron intensities I(2,1) to I(2,N) can be measured using the beam 2, and secondary electron intensities I (3,1) to I(3,N) can be measured using the beam 3, for example. By similarly performing measurement using each primary electron beam 10, the secondary electron intensity measurement circuit 129 can measure secondary electron intensities I (1,1) to I(N,N) per unit of sub-irradiation region 29 (per unit of primary electron beam). Information on measured secondary electron intensities I (1,1) to I(N,N) is output to the gain calculation circuit 130.

In the gain calculation step (S104), the gain calculation circuit 130 calculates a gain value for each detection sensor 223 and each primary electron beam 10. Specifically, the gain calculation circuit 130 calculates, as a gain value, a ratio between an intensity value of the secondary electron beam 12 due to irradiation with the primary electron beam 10 concerned detected by the detection sensor 223 which is for detecting the secondary electron beam 12 due to irradiation with the primary electron beam 10 concerned, and an intensity value of the secondary electron beam 12 due to another primary electron beam 10 detected by the same detection sensor 223.

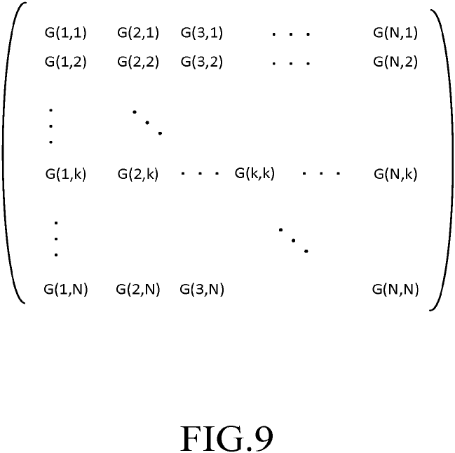

FIG. 9 is an illustration of an example of a gain map according to the embodiment 1. In FIG. 9, with respect to a gain value G(A,B), A indicates a beam number and B indicates a detection sensor number. A is one of values 1 to N, and B is one of 1 to N. A gain value G(m,k) of a beam m (primary electron beam) in a detection sensor k for a beam k (primary electron beam) is defined by the following equation (1).

$$\text{G} \left(\text{m, k}\right) = \text{I} \left(\text{m, k}\right) / \text{I} \left(\text{k, k}\right)$$

By calculating a gain value for each detection sensor 223 and each primary electron beam 10, gain values G (1,1) to G(N,N) can be acquired as shown in FIG. 9. Thus, a gain map whose elements are these gain values G (1,1) to G(N,N) can be generated. With respect to gain values G (1,1), G(2,2), ..., G(N,N) in which the beam number is the same as the detection sensor number, since it becomes 1 as apparent from the equation (1), calculation may be omitted.

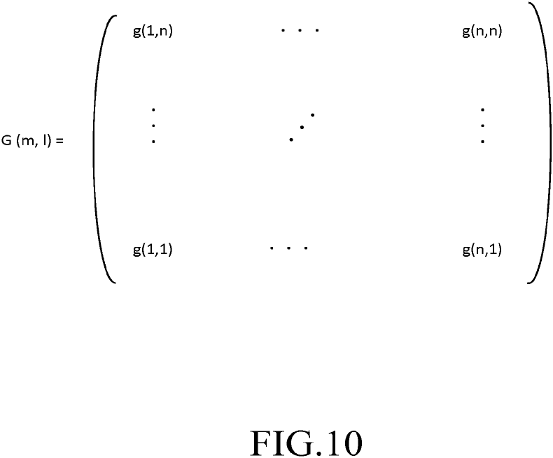

FIG. 10 is an illustration of an example of a configuration of each gain value according to the embodiment 1. Since each of secondary electron intensities I (1,1) to I(N,N) is configured by a map whose elements are secondary electron intensities i(1,1) to i(n,n) of respective pixels as shown in FIG. 7, each of gain values G (1,1) to G(N,N) is also configured by a map whose elements are g(1,1) to g(n,n) of respective pixels as shown in FIG. 10. In other words, the gain value may be different for each pixel. The generated gain map is stored in the storage device 109.

After carrying out processes described above as preprocessing, the substrate 101 to be inspected is arranged on the stage 105, and actual inspection processing is performed.

In the secondary electron image acquisition step (S106), while moving the stage 105 at a constant speed, the image acquisition mechanism 150 irradiates the substrate 101, on which a plurality of figure patterns are formed, with the multiple primary electron beams 20, detects the multiple secondary electron beams 300 emitted from the substrate 101 due to the irradiation by the multiple primary electron beams 20, and acquires a secondary electron image of a figure pattern for each sub-irradiation region 29. As described above, reflected electrons and secondary electrons may be projected on the multi-detector 222, or after reflected electrons having been emitted along the way, remaining secondary electrons may be projected.

As described above, in order to acquire an image, the substrate 101 is irradiated with the multiple primary electron beams 20, and the multi-detector 222 detects the multiple secondary electron beams 300 including reflected electrons emitted from the substrate 101 due to the irradiation by the multiple primary electron beams 20. Detected data (measured image data: secondary electron image data: inspection image data) on the secondary electron of each pixel in each sub-irradiation region 29, detected by the multi-detector 222, is output to the detection circuit 106 in the order of measurement. In the detection circuit 106, the detected data in analog form is converted into digital data by an A-D converter (not shown), and stored in the chip pattern memory 123. Then, measured image data having been acquired is transmitted to the comparison circuit 108, together with information on each position from the position circuit 107. It goes without saying that, in the secondary electron image data for each pixel acquired here, a crosstalk image component is still included.

In the reference image generation step (S110), the reference image generation circuit 112 (reference image data generation unit) generates a reference image corresponding to a mask die image, based on design data serving as a basis of a plurality of figure patterns formed on the substrate 101. In other words, the reference image generation circuit 112 generates reference image data of a pixel (position) irradiated with each primary electron beam. Specifically, it operates as follows: First, design pattern data is read from the storage device 109 through the control computer 110, and each figure pattern defined by the read design pattern data is converted into image data of binary or multiple values.

As described above, basic figures defined by the design pattern data are, for example, rectangles and triangles. For example, there is stored figure data defining the shape, size, position, and the like of each pattern figure by using information, such as coordinates (x,y) of the reference position of the figure, lengths of sides of the figure, and a figure code serving as an identifier for identifying the figure type such as rectangles and triangles.

When design pattern data used as the figure data is input to the reference image generation circuit 112, the data is developed into data for each figure. Then, the figure code, the figure dimensions, and others indicating the figure shape of the figure data are interpreted. Then, it is developed into design pattern image data of binary or multiple values as a pattern to be arranged in squares in units of grids of predetermined quantization dimensions, and then is output. In other words, the reference image generation circuit 112 reads design data, calculates the occupancy of a figure in the design pattern, for each square obtained by virtually dividing the inspection region into squares in units of predetermined dimensions, and outputs n-bit occupancy data. For example, it is preferable to set one square as one pixel. Assuming that one pixel has a resolution of ½⁸(=1/256), the occupancy rate in each pixel is calculated by allocating sub-regions, each having 1/256 resolution, which correspond to the region of a figure arranged in the pixel. Then, it becomes 8-bit occupancy rate data. Such squares (inspection pixels) may be commensurate with pixels of measured data.

Next, the reference image generation circuit 112 performs filtering processing on design image data of a design pattern which is image data of a figure, using a predetermined filter function. Thereby, it becomes possible to match the design image data being design side image data, whose image intensity (gray scale level) is represented by digital values, with image generation characteristics obtained by irradiation with the multiple primary electron beams 20. Image data for each pixel of a generated reference image is output to the synthesis circuit 132.

In the synthesis step (S112), the synthesis circuit 132 (synthesis unit) synthesizes, for each primary electron beam 10, reference image data of a pixel (position) irradiated with the primary electron beam 10 concerned and portions of a plurality of reference image data of pixels (positions) irradiated with other primary electron beams different from the primary electron beam 10 concerned. Specifically, the synthesis circuit 132 synthesizes, for each primary electron beam, a value of the reference image data of the position irradiated with the primary electron beam concerned, and a value obtained by multiplying a value of reference image data of a position irradiated with another primary electron beam different from the primary electron beam concerned by a gain value for the another primary electron beam.

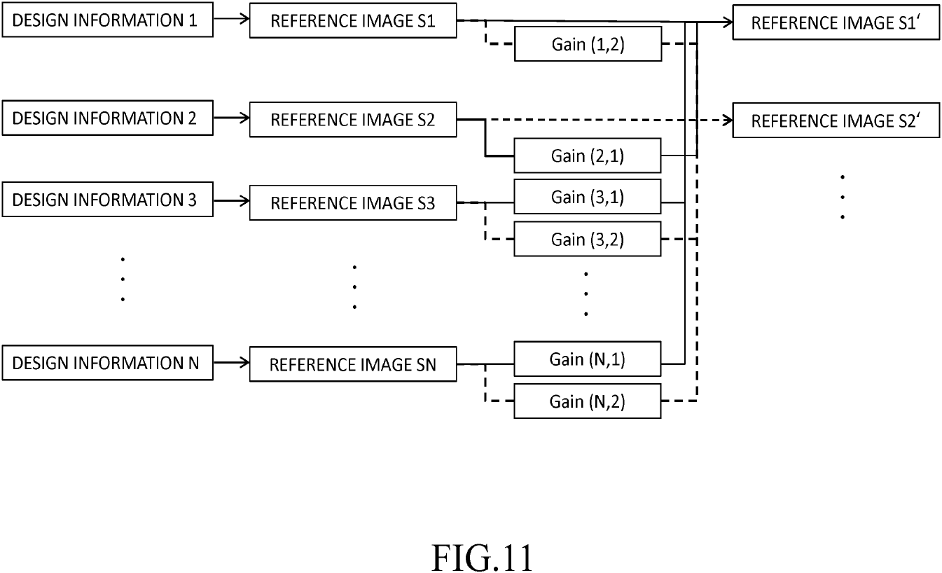

FIG. 11 is an illustration of a method for generating a synthetic reference image according to the embodiment 1. In FIG. 11, “Gain (1,2)” indicates a “gain value G(1,2)”. A synthetic reference image S1′ is generated by adding a reference image S1 of the sub-irradiation region 29 scanned with a beam 1 (primary electron beam 10) and values each obtained by multiplying a reference image S2, ..., SN of the sub-irradiation region 29 scanned with other beam 2, ..., N (primary electron beam 10) by each corresponding gain value G(2,1), ..., G (N,1) . Similarly, a synthetic reference image S2′ is generated by adding a reference image S2 of the sub-irradiation region 29 scanned with a beam 2 (primary electron beam 10) and values each obtained by multiplying a reference image S1, S3, ..., SN of the sub-irradiation region 29 scanned with other beam 1, 3, ..., N (primary electron beam 10) by each corresponding gain value G (1,2) , G(3,2), ..., G(N,2). Similarly, hereinafter, a synthetic reference image SN′ is generated by adding a reference image SN of the sub-irradiation region 29 scanned with a beam N (primary electron beam 10) and values each obtained by multiplying a reference image S1, ..., S(N-1) of the sub-irradiation region 29 scanned with other beam 1, ..., N-1 (primary electron beam 10) by each corresponding gain value G (1,N) , ..., G (N-1,N) . In other words, it can be define by the following equations (2-1) to (2-N).

$$\text{S} {\text{1}}^{′} = \text{S1} ⋅ \text{G} \left(\text{1,1}\right) + \text{S2} ⋅ \text{G} \left(2 , 1\right) + … + \text{SN} ⋅ \text{G} \left(\text{N} , 1\right)$$

$$\text{S} {\text{2}}^{′} = \text{S1} ⋅ \text{G} \left(\text{1,2}\right) + \text{S2} ⋅ \text{G} \left(2 , 2\right) + … + \text{SN} ⋅ \text{G} \left(\text{N} , 2\right)$$

Similarly, hereinafter,

$$\text{S} {\text{N}}^{′} = \text{S1} ⋅ \text{G} \left(\text{1,N}\right) + \text{S2} ⋅ \text{G} \left(2 , \text{N}\right) + … + \text{SN} ⋅ \text{G} \left(\text{N} , \text{N}\right)$$

As described above, with respect to a gain value G(1,1), G(2,2), ..., G(N,N) in which the beam number is the same as the detection sensor number, since any calculation results in 1, it may be omitted.

Each of the synthetic reference images S1′ to SN′ is an image of the sub-irradiation region 29 scanned with each main beam (primary electron beam 10). Therefore, each of the synthetic reference images S1′to SN′ is configured by synthetic reference image data for each pixel. Image data of a generated synthetic reference image for each pixel is output to the comparison circuit 108.

The example described above shows the case where, when generating each synthetic reference image, values each obtained by multiplying each of reference images of all the primary electron beams by each corresponding gain value are added, however, it is not limited thereto. As shown in the example of FIG. 5, the range where crosstalk occurs may be restricted to detection sensors for about eight to twenty beams around the target beam. Therefore, instead of calculating values each obtained by multiplying each of reference images of all the primary electron beams by each corresponding gain value, it may be sufficient to calculate values each obtained by multiplying each of reference images of surrounding eight to twenty primary electron beams by each corresponding gain value. Accordingly, it is also preferable to generate synthetic reference image data by synthesizing reference image data of a position irradiated with the primary electron beam 10 concerned and a portion of reference image data of positions irradiated with other primary electron beams, whose number is less than that of the multiple primary electron beams 20. The range where crosstalk occurs may be set previously.

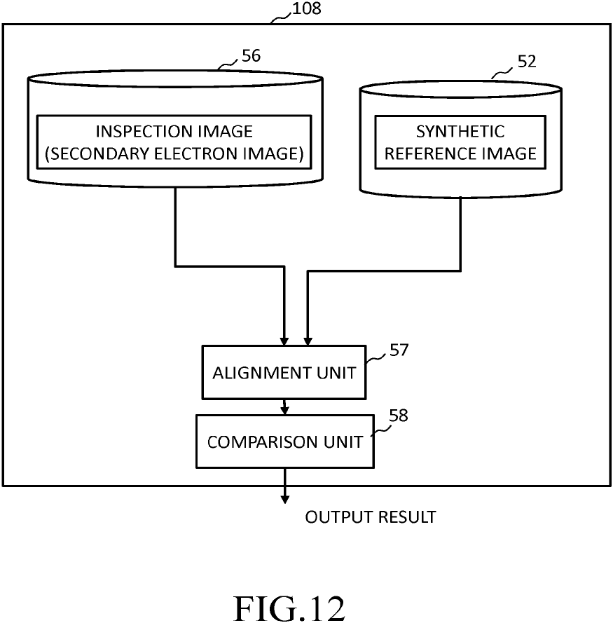

FIG. 12 is a block diagram showing an example of a configuration in a comparison circuit according to the embodiment 1. In FIG. 12, in the comparison circuit 108, there are arranged storage devices 52 and 56 such as magnetic disk drives, an alignment unit 57 and a comparison unit 58. Each of the “units” such as the alignment unit 57 and the comparison unit 58 includes processing circuitry. The processing circuitry includes an electric circuit, a computer, a processor, a circuit board, a quantum circuit, a semiconductor device or the like. Further, common processing circuitry (the same processing circuitry), or different processing circuitry (separate processing circuitry) may be used for each of the “units”. Input data required in the alignment unit 57 and the comparison unit 58, or calculated results are stored in a memory (not shown) or in the memory 118 each time.

According to the embodiment 1, the sub-irradiation region 29 acquired by scanning with one primary electron beam 10i is further divided into a plurality of mask die regions. The mask die region is used as a unit region of an image to be inspected. In order to prevent missing an image, it is preferable that the margin region of each mask die region overlaps each other.

In the comparison circuit 108, transmitted measured image data (secondary electron image data) is temporarily stored in the storage device 56, as a mask die image (inspection image to be inspected) of each mask die region. Similarly, transmitted synthetic reference image data is temporarily stored in the storage device 52, as a synthetic reference image for each mask die region.

In the alignment step (S120), the alignment unit 57 reads a mask die image serving as an inspection image, and a synthetic reference image corresponding to the mask die image, and provides alignment between the images based on units of sub-pixels smaller than pixels. For example, the alignment can be performed by a least-square method.

In the comparison step (S122), the comparison unit 58 compares, for each pixel, a mask die image (secondary electron image) and a synthetic reference image. In other words, the comparison unit 58 compares synthetic reference image data having been synthesized, and secondary electron image data based on a value detected by the detection sensor 223 which detects a secondary electron beam due to irradiation with the primary electron beam concerned. Explaining further, the comparison unit 58 compares secondary electron image data including a crosstalk image component, and synthetic reference image data having been corrected to include the crosstalk image component. Highly accurate defect detection suppressing a pseudo defect can be achieved by decreasing the accuracy of reference image data so that it may be matched with the accuracy of secondary electron image data instead of increasing the accuracy of the secondary electron image data. The comparison unit 58 compares the both, for each pixel, based on predetermined determination conditions in order to determine whether or not there is a defect such as a shape defect. For example, if a difference in gray scale value for each pixel is larger than a determination threshold Th, it is determined that there is a defect. Then, the comparison result may be output to the storage device 109, the monitor 117, or the memory 118, or alternatively, output from the printer 119.

As described above, according to the embodiment 1, it is possible to perform an inspection with high accuracy even when, into the sensor for each beam, a secondary electron of a beam not concerned is mixed, namely occurrence of so-called crosstalk.

In the above description, a series of “... circuits” includes processing circuitry. The processing circuitry includes an electric circuit, a computer, a processor, a circuit board, a quantum circuit, a semiconductor device, or the like. Each “... circuit” may use common processing circuitry (the same processing circuitry), or different processing circuitry (separate processing circuitry). A program for causing a processor, etc. to execute processing may be stored in a recording medium, such as a magnetic disk drive, magnetic tape drive, FD, or ROM (Read Only Memory). For example, the position circuit 107, the comparison circuit 108, the reference image generation circuit 112, the stage control circuit 114, the lens control circuit 124, the blanking control circuit 126, the deflection control circuit 128, the secondary electron intensity measurement circuit 129, the gain calculation circuit 130, and the synthesis circuit 132 may be configured by at least one processing circuit described above.

Embodiments have been explained referring to specific examples as described above. However, the present invention is not limited to these specific examples. Although FIG. 1 shows the case where the multiple primary electron beams 20 are formed by the shaping aperture array substrate 203 irradiated with one beam from the electron gun 201 serving as an irradiation source, it is not limited thereto. The multiple primary electron beams 20 may be formed by irradiation with a primary electron beam from each of a plurality of irradiation sources.

While the apparatus configuration, control method, and others not directly necessary for explaining the present invention are not described, some or all of them can be appropriately selected and used on a case-by-case basis when needed.

Further, any multi-electron beam inspection apparatus and multi-electron beam inspection method that include elements of the present invention and that can be appropriately design-modified by those skilled in the art are included within the scope of the present invention.

### INDUSTRIAL APPLICABILITY

The present invention relates to a multi-electron beam inspection apparatus and a multi-electron beam inspection method. For example, it can be applied to an inspection apparatus that performs an inspection using a secondary electron image of a pattern, emitted due to irradiation of electron multiple beams.

### Reference Signs List

| | |
|---|---|
| 10 | Primary Electron Beam |
| 12 | Secondary Electron Beam |
| 20 | Multiple Primary Electron Beams |
| 22 | Hole |
| 29 | Sub-irradiation Region |
| 32 | Stripe Region |
| 33 | Frame Region |
| 34 | Irradiation Region |
| 52, 56 | Storage Device |
| 57 | Alignment Unit |
| 58 | Comparison Unit |
| 100 | Inspection Apparatus |
| 101 | Substrate |
| 102 | Electron Beam Column |
| 103 | Inspection Chamber |
| 105 | Stage |
| 106 | Detection Circuit |
| 107 | Position Circuit |
| 108 | Comparison Circuit |
| 109 | Storage Device |
| 110 | Control Computer |
| 112 | Reference Image Generation Circuit |
| 114 | Stage Control Circuit |
| 117 | Monitor |
| 118 | Memory |
| 119 | Printer |
| 120 | Bus |
| 122 | Laser Length Measurement System |
| 123 | Chip Pattern Memory |
| 124 | Lens Control Circuit |
| 126 | Blanking Control Circuit |
| 128 | Deflection Control Circuit |
| 129 | Secondary Electron Intensity Measurement Circuit |
| 130 | Gain Calculation Circuit |
| 132 | Synthesis circuit |
| 142 | Drive Mechanism |
| 144, 146, 148 | DAC amplifier |
| 150 | Image Acquisition Mechanism |
| 160 | Control System Circuit |
| 200 | Electron Beam |
| 201 | Electron Gun |
| 202 | Electromagnetic Lens |
| 203 | Shaping Aperture Array Substrate |
| 205, 206, 207, 224, 226 | Electromagnetic Lens |
| 208 | Main Deflector |
| 209 | Sub Deflector |
| 212 | Bundle Blanking Deflector |
| 213 | Limiting Aperture Substrate |
| 214 | Beam Separator |
| 216 | Mirror |
| 218 | Deflector |
| 219 | Beam Selection Aperture Substrate |
| 222 | Multi-Detector |
| 223 | Detection Sensor |
| 300 | Multiple Secondary Electron Beams |
| 330 | Inspection Region |
| 332 | Chip |

1. A multi-electron beam inspection apparatus comprising:
a stage configured to mount thereon a target object on which a pattern is formed;
a primary electron optical system configured to apply multiple primary electron beams to the target object;
a multi-detector configured to include a plurality of detection sensors each of which detects a secondary electron beam emitted due to that the target object is irradiated with a primary electron beam individually preset in the multiple secondary electron beams emitted because the target object is irradiated with the multiple primary electron beams;
a reference image data generation circuit configured to generate reference image data of a position irradiated with each primary electron beam, based on design data serving as a basis of the pattern formed on the target object;
a synthesis circuit configured to synthesize, for the each primary electron beam, the reference image data of the position irradiated with a primary electron beam concerned and portions of a plurality of reference image data of positions irradiated with other primary electron beams different from the primary electron beam concerned; and
a comparison circuit configured to compare synthetic reference image data having been synthesized, and secondary electron image data based on a value detected by the detection sensor which detects a secondary electron beam due to irradiation with the primary electron beam concerned.

2. The multi-electron beam inspection apparatus according to claim 1, wherein, for the each primary electron beam, a value of the reference image data of the position irradiated with the primary electron beam concerned is synthesized with a value obtained by multiplying a value of reference image data of a position irradiated with another primary electron beam different from the primary electron beam concerned by a gain value for the another primary electron beam.

3. The multi-electron beam inspection apparatus according to claim 2, further comprising:
a gain calculation circuit configured to calculate, as the gain value, a ratio between an intensity value of the secondary electron beam due to the irradiation with the primary electron beam concerned detected by the sensor detecting the secondary electron beam due to the irradiation with the primary electron beam concerned, and an intensity value of a secondary electron beam due to the another primary electron beam detected by the sensor.

4. The multi-electron beam inspection apparatus according to claim 1, wherein the synthetic reference image data is generated by synthesizing the reference image data of the position irradiated with the primary electron beam concerned, and the portions of the plurality of reference image data of the positions irradiated with the other primary electron beams, whose number is less than that of the multiple primary electron beams.

5. The multi-electron beam inspection apparatus according to claim 1, wherein the synthetic reference image data is generated by synthesizing the reference image data of the position irradiated with the primary electron beam concerned, and the portions of the plurality of reference image data of the positions irradiated with a plurality of primary electron beams around the primary electron beam concerned.

6. A multi-electron beam inspection method comprising:
applying multiple primary electron beams to a target object on which a pattern is formed;
detecting, by using a multi-detector which includes a plurality of detection sensors each of which detects a secondary electron beam emitted due to that the target object is irradiated with a primary electron beam individually preset in multiple secondary electron beams emitted because the target object is irradiated with the multiple primary electron beams, the multiple secondary electron beams emitted due to that the target object is irradiated with the multiple primary electron beams, and acquiring secondary electron image data of each of the detection sensors, based on a detected value of the each of the detection sensors;
generating reference image data of a position irradiated with each primary electron beam, based on design data serving as a basis of the pattern formed on the target object;
synthesizing, for the each primary electron beam, the reference image data of the position irradiated with the primary electron beam concerned and portions of a plurality of reference image data of positions irradiated with other primary electron beams different from the primary electron beam concerned; and
comparing synthetic reference image data having been synthesized, and secondary electron image data based on a value detected by the detection sensor which detects a secondary electron beam due to irradiation with the primary electron beam concerned.

7. The multi-electron beam inspection method according to claim 6, wherein, for the each primary electron beam, a value of the reference image data of the position irradiated with the primary electron beam concerned is synthesized with a value obtained by multiplying a value of reference image data of a position irradiated with another primary electron beam different from the primary electron beam concerned by a gain value for the another primary electron beam.

8. The multi-electron beam inspection method according to claim 7, wherein, as the gain value, a ratio is calculated between an intensity value of the secondary electron beam due to the irradiation with the primary electron beam concerned detected by the sensor which detects the secondary electron beam due to the irradiation with the primary electron beam concerned, and an intensity value of a secondary electron beam due to the another primary electron beam detected by the sensor.

9. The multi-electron beam inspection method according to claim 6, wherein the synthetic reference image data is generated by synthesizing the reference image data of the position irradiated with the primary electron beam concerned, and the portions of the plurality of reference image data of the positions irradiated with the other primary electron beams, whose number is less than that of the multiple primary electron beams.

10. The multi-electron beam inspection method according to claim 6, wherein the synthetic reference image data is generated by synthesizing the reference image data of the position irradiated with the primary electron beam concerned, and the portions of the plurality of reference image data of the positions irradiated with a plurality of primary electron beams around the each primary electron beam concerned.
